(19) United States
(12) Patent Application Publication
(10) Pub. No.: US 2008/0061285 A1
(43) Pub. Date: Mar. 13, 2008

(54) Metal layer inducing strain in silicon

(75) Inventors: Reza Arghavani, Scotts Valley, CA (US); Jianming Fu, Palo Alto, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc.

(21) Appl. No.: 11/490,884

(22) Filed: Jul. 21, 2006

(51) Int. Cl. H01L 29/06; H01L 21/336

(52) U.S. Cl. 257/20; 257/192; 438/285; 257/E29.104

(57) ABSTRACT

A metal layer, especially a metal compound, induces strain into a gate channel of a MOS transistor. Compressive strain of over 4 GPa is available from sputter deposited TiN. The amount of strain can be controlled at least up to 11 GPa, for example, by wafer biasing. The compressive strain may induce compressive strain in a PMOS channel when deposited around the channel and induce tensile strain in an NMOS channel when deposited over the channel.

### FIELD OF THE INVENTION

The invention relates generally to semiconductor devices and their formation. In particular, the invention relates to semiconductor devices incorporating strained silicon and the method of straining it by sputter depositing a metal layer.

### BACKGROUND ART

The continuing advance of silicon integrated circuits has been characterized by Moore's Law, which states that the number of devices doubles every 18 months on the most advanced integrated circuit chips then available. At the present time, an advanced integrated circuit includes several billions of transistors.

This continuing advance in integration is largely accomplished by the shrinkage of the size of the individual active components constituting the integrated circuits. Advances in photolithography partially enabled the advances but other features such as shallower and more highly doped junctions and low-k dielectrics have also been required. Currently, 65 nm devices are entering production and 45 nm devices are under development. One advantage of the shrinking sizes is that the operational speeds of switching transistors increases with decreasing size. It is desired to continue this upward trend in integration. However, advances are becoming more difficult and may likely require more fundamental changes.

Devices incorporating strained silicon have recently been introduced. The strain enables the fabrication of faster transistors without a commensurate reduction in feature sizes. It is known that compressively strained silicon has a higher hole mobility than unstrained silicon. On the other hand, tensile strained silicon has a higher electron mobility than unstrained silicon. Some of the older techniques for introducing strain include the epitaxial growth of a layer of silicon and a layer of a silicon-germanium (SiGe). Because of the differing lattice constants of the two materials, the after-grown layer is grown with built in stress as long as its thickness is not too large. In one technique, SiGe is regrown in source and drain regions recessed in silicon, which transfers strain into the intermediate silicon gate channel. More recently developed techniques include the chemical vapor deposition (CVD) of dielectric layers, for example, of silicon nitride or silicon dioxide, upon underlying silicon under conditions in which the nitride or oxide is strained. The stress in the dielectric layer may be at least partially transferred into the silicon to affect its mobility.

An example of a MOS (metal-oxide-semiconductor) transistor 10, also called a MOS field effect transistor (MOSFET) is displayed in the cross-sectional view of FIG. 1. Because a first embodiment of the invention is implemented in a p-type MOS (PMOS) transistor, doping types proper to PMOS will be described. However, the description is applicable to n-type MOS (NMOS) transistor with a simple reversal of doping types. A PMOS transistor 10 is formed at the surface of a silicon substrate 12 having a lightly doped n-type well at its surface formed by ion implantation. The PMOS transistor 10 is surrounded by a shallow trench isolation (STI) 14 formed of silicon oxide deposited into a trench in the silicon substrate 12. The shallow trench isolation 14 surrounds one or a limited number of transistors to electrically isolate them from other transistors. The transistor gate is formed by a gate channel (G) 16 formed in the surface of the n-type well of the silicon substrate 12. A thin gate oxide 18 is deposited over or oxidized from the silicon of the channel 16 and a heavily doped polysilicon gate electrode 20 is deposited and defined over the gate oxide 18. The sides of the polysilicon gate electrode 20 may be oxidized to form a liner 22. A nitride spacer 24 is patterned around the gate electrode 20 and its foot. This structure may be modified to a flash memory by including an oxide-nitride-oxide (ONO) tunneling storage cell in the gate electrode 20.

Prior to the formation of the liner 22 and the spacer 24, the gate electrode 20 may act as an implant mask for a medium angular doping implant of p-type dopants into shallow extensions 30, 32 of deeper source and drains (S and D) 34, 36 later formed by ion implantation of a heavier dose of the p-type dopants using the gate spacer 24 as a mask. Nickel silicide ohmic contacts 40, 42, 44 are formed over the polysilicon gate electrode 20 and the silicon source and drain 34, 36 by depositing a layer of nickel and annealing it to form a silicide with the underlying silicon in order to provide ohmic contacts between the silicon and later formed vertical metalllizations.

An etch stop layer 50 and a pre-metal dielectric layer 52 are conformally deposited, typically by chemical vapor deposition, over the gate electrode 20 and the planar regions of the substrate 12. Typically, the etch stop layer is composed of silicon nitride of the approximate composition Si₃N₄, and the pre-metal dielectric layer 52 is composed of silicon dioxide (SiO₂), usually called silicon oxide, or more preferably in advanced devices a low-k dielectric, which may be formed of doped silicon oxide. Holes are etched through first the pre-metal dielectric layer 52 and then the etch stop layer 50 and then filled with a metallization such as tungsten to form unlanded source and drain contacts 54, 56 and a gate contact 58.

Recently, strain has been introduced into the structure of FIG. 1 by a number of techniques. In one technique, the source and drain 34, 36 may be formed in regions of silicon-germanium alloy epitaxially regrown in areas etched into the silicon substrate 12. The compressive strain introduced by the SiGe, which is pseudomorphic with the silicon of smaller lattice spacing, is transferred into the channel 16 so that it too is strained. In another technique, described by Arghavani et al. in U.S. Patent Application Publication 2005/0255667, the oxide in the shallow trench isolation 14 is grown in tensile strain, which is transferred into the MOS transistor 10.

In a further technique, described by Arghavani in U.S. patent application Ser. No. 11/037,684, filed Jan. 15, 2005, and now published as U.S. Patent Application Publication 2006/0160314, the nitride etch stop layer 50 is grown under CVD conditions producing strain. It is also possible to induce strain from the oxide liner 22 or from the pre-metal dielectric 52. Also, the silicide ohmic contacts layers 40, 42, 44 can be grown to induce strain.

Although these techniques for introducing strain have been effective at increasing the carrier mobility and hence the speed of silicon integrated circuits, present techniques have been capable of producing a maximum of about 3 gigapascals (GPa) of stress, and this stress level s often significantly reduced when transferred into a neighboring silicon layer. The amount of stress which can be transferred to the underlying silicon depends in part on the area of the stress inducing layer and the geometry of the structure. As the spacing between gates decreases for advanced integrated circuits, the nitride and oxide strain-inducing layers have become insufficient. Greater stress and strain levels are desired for future generations of integrated circuits.

### SUMMARY OF THE INVENTION

Strain may be induced into a silicon MOS transistor or other silicon device by a metal layer of a metal compound which is deposited adjacent to the transistor.

The metal compound may be a metal nitride. Titanium nitride may be grown with compressive strain of 4 gigapascal and greater by plasma reactive sputtering.

A compressively strained metal layer, for example, of TiN, may induce compressive strain into a MOS gate channel when deposited around but not over the channel, which is advantageous for a PMOS transistor. Alternatively, it may induce tensile strain into a MOS gate when deposited over the channel, which is advantageous for an NMOS transistor.

### BRIEF DESCRIPTION OF THE DRAWINGS

FIG. 1 is a cross-sectional view of a conventional metal-oxide-semiconductor (MOS) transistor.

FIG. 2 is a cross-sectional view of a first embodiment of a MOS transistor of the invention incorporating a metal strain-inducing layer around the gate channel.

FIG. 3 is a cross-sectional view a second embodiment of a MOS transistor of the invention incorporating a metal strain-inducing layer over the gate channel.

FIG. 4 a schematic cross-sectional view of a sputter chamber which may be used with the invention.

FIG. 5 is a graph of dependences of compressive stress and sheet resistance produced in a titanium nitride film under different sputtering conditions.

FIG. 6 is a graph of the dependence of compressive stress produced in titanium nitride films of differing thickness sputter deposited on different substrates.

FIG. 7 is a graph of the dependence of compressive stress produced in titanium nitride films sputter deposited on different substrate at different values of wafer bias.

### DETAILED DESCRIPTION OF THE PREFERRED EMBODIMENTS

According to one aspect of the invention, a metal layer is deposited adjacent to a silicon channel to impart a high and controlled level of strain to the channel. The strain may be chosen to increase the carrier mobility in the semiconducting channel. An example of the metal layer is titanium nitride (TiN) deposited by reactive sputtering, also called physical vapor deposition (PVD). The sputtering conditions can be controlled to impart a desired level of strain to the channel. Strain levels of up to −12 gigapascals (GPA) have been repeatable observed in reactively sputtered TiN, far in excess of the −3 GPa currently available in strain-inducing layers of silicon oxide and silicon nitride grown by CVD.

According to one embodiment of a strained MOS transistor 60, illustrated in the cross-sectional view of FIG. 2, a metal compression layer 62 is formed around the gate electrode 20 to provide compressive strain. The geometry is such that the compressive strain of the metal compression layer 62 places the underlying silicon into tensile strain, which in turn pushes against the surrounded silicon of the gate channel 16, thus inducing the desired compressive strain in the channel. The compressive stain increases the hole mobility within the semiconducting silicon channel 16 and hence increases the speed of a p-type metal-oxide-semiconductor (PMOS) transistor.

The compression layer 62 is formed for example, of titanium nitride (TiN), which can be reactively sputtered with the desired compressive strain. Initial results have shown that TiN can be grown with stress of up to 10 GPa. Titanium nitride is a well known material otherwise used in forming barrier layers in via holes through inter-level dielectric layers in the upper metallization layers in integrated circuits. Its propensity to be strained when formed by reactive sputtering is known and generally the strain was considered to be a negative effect since it degrades reliability.

In the illustrated embodiment, the metal compression layer 62 is deposited over the nitride etch stop layer 50. Other structures are possible. For example, the nitride etch stop 50 may be replaced by a silicon oxide layer having little or no strain but providing an insulator layer to the underlying conductive features. However, the illustrated embodiment has the advantage that the nitride can be grown to have a moderate amount of tensile strain and extend adjacent the sides of the NMOS transistor, providing the desired tensile strain to the NMOS transistor. The metal compression layer 62 is then grown over the nitride layer 50 only in the area of the PMOS transistor under conditions producing a much larger compressive stress to overcompensate the nitride's tensile stress on the PMOS transistor. Thereby, the PMOS transistor is under compressive strain while the NMOS transistor is under tensile strain, as desired. Alternatively, the overlying pre-metal dielectric layer 52 could be deposited with a moderate amount of tensile strain, which would be over compensated by the high compressive strain of the metal compression layer 62.

Titanium nitride has a moderately high electrical conductivity, unlike silicon oxide or silicon nitride, and thus can be considered a metal rather than a dielectric. Accordingly, the TiN compression layer 62 needs to be patterned to avoid the metallized contacts 54, 56, 58 so as to not short out the metal-filled contacts. Silicided contact strain-inducing layers of the prior art avoid the shorting problem because they are in the intended conduction path and are already isolated from other contacts. The patterned etching of titanium nitride may be performed by techniques developed for aluminum etching, for example, using a chlorine-based plasma. Wang et al. describe an integrated aluminum etching process in U.S. Patent Application Publication 2004/0074869.

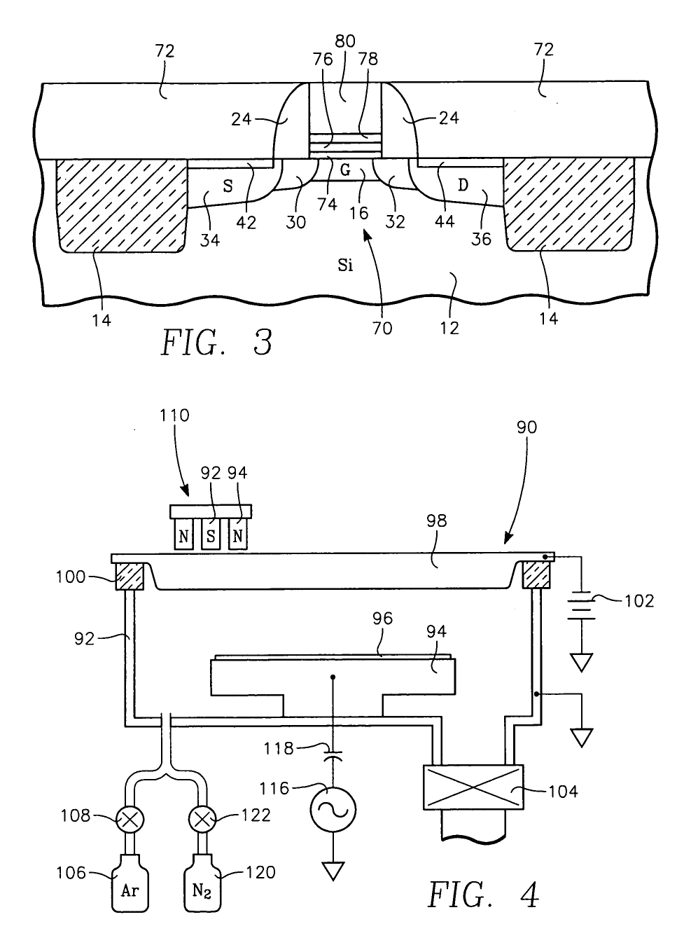

Another embodiment of the invention illustrated in the cross-sectional view of FIG. 3 is based upon a replacement gate of the type described by Li in U.S. Patent Application Publication 2005/0282329 and by Kudo et al. in U.S. Patent Application Publication 2004/0142546. Geometrical effects allow compressive TiN to induce tensile strain in the underlying gate channel, which is particularly valuable for NMOS transistors, which are paired with the previously described PMOS transistor in the conventional CMOS integrated circuits widely used in advanced logic circuitry.

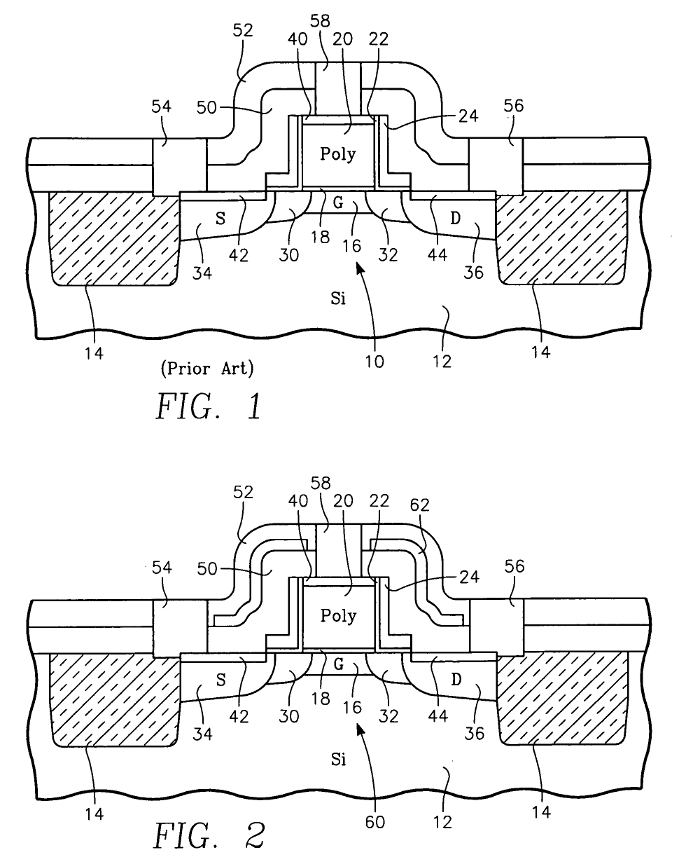

A replacement gate MOS transistor may be fabricated similarly to the early steps used in the polysilicon-gate transistor of FIG. 1. However, the polysilicon gate electrode 20 is a sacrificial electrode which will be later removed. As illustrated in the cross-sectional view of FIG. 3 for a replacement gate transistor 70, after the spacers 24 have been formed around the polysilicon gate electrode, the source and drain implants have been performed, and the source and drain ohmic contacts 42, 44 have been silicided, a dielectric layer 72 is deposited over the surface and planarized with the top of the spacers 24 and the sacrificial polysilicon gate electrode, for example, by chemical mechanical polishing. The dielectric layer 72 may include the etch stop layer but be principally composed of a low-k dielectric to serve as the pre-metal dielectric. The polysilicon is then removed from between the spacers 24. A thin high-k gate dielectric layer 74 is formed at the bottom of the hole either prior to the forming the sacrificial gate electrode or after its removal. Exemplary high-k dielectrics are HfO, ZrO, and Al₂O₃. A gate electrode layer 76 is deposited over the gate dielectric layer 74. It is formed of a metal or metal alloy chosen to have the proper work function for the doping type of the gate channel 16, for example, TiSi for an NMOS transistor or TiAl for a PMOS transistor.

According to this embodiment of the invention, a compressively strained metal layer 78 is formed over the gate electrode layer 76. Titanium nitride, as described above, is a preferred material for the compression-inducing metal layer 78. One of more of the layers 74, 76, 78 may be conformally deposited on the hole sidewall and possibly over the outside of the spacers 24 depending upon the deposition process and when it is performed. A metallization metal, for example, of aluminum is deposited by PVD to fill and overfill the remainder of the hole. CMP removes the metallization metal outside of the hole leaving a gate contact metallization 80. Further processing forms the source and drain contacts 54, 56 of FIG. 2. However, in other processes, the dielectric layer 72 is removed and replaced by another one.

The compressively strained layer 78 of TiN overlies the silicon gate channel 16 and causes the gate channel 16 in reaction to go into tensile strain, as desired for an NMOS transistor. Thus, a strain-inducing layer of the same composition and having the same type of strain can induce either tension or compression into the silicon channel depending on the geometry relating the strain-inducing layer and the channel.

The transistors 60, 70 of FIGS. 2 and 3 may be respectively applied to the PMOS and NMOS transistor of an integrated circuit, or the gate replacement transistor 70 may be used for the NMOS transistor and other means may be used to provide the desired compressive strain in PMOS transistor. Further, the strain-inducing metal layer may be combined with other methods and structures providing the same or opposite strain, for example, those mentioned in the background section.

The strain-inducing nitride and oxide layers of the prior art are typically deposited by chemical vapor deposition. The strain-inducing metal layer of the invention may be economically and effectively deposited by sputtering from a metal target. A plasma sputter chamber 90 is schematically illustrated in the cross-sectional view of FIG. 4. A vacuum chamber 92 includes a pedestal electrode 94 to support a wafer 96 to be sputter coated with a material of a target 98 in opposition to the wafer 96. For sputtering TiN, at least the front surface of the target 98 is composed of titanium. The vacuum chamber 92, which is typically electrically grounded, supports the target 98 through an isolator 100. A DC power supply 102 electrically biases the target 98 to a negative voltage in the range of about 600 to 800VDC to support a plasma within the vacuum chamber 92.

A vacuum pump system 104 pumps the vacuum chamber to a base pressure in the microTorr range or below. An argon gas source 106 supplies argon as a sputter working gas into the vacuum chamber 92 through a mass flow controller 108. When the argon pressure within the vacuum chamber 92 is held in the low milliTorr range, the negative voltage applied to the target 98 in opposition to the grounded chamber or to unillustrated grounded chamber shields excites the argon into a plasma. The positively charged argon ions are attracted to the negatively biased target 98 and sputter titanium atoms from it, some of which strike the wafer and coat it. A magnetron 110 typically comprising an inner pole 112 of one magnetic polarity and an surrounding and stronger outer pole 114 of the opposite polarity is disposed in back of the target 98 to generate a magnetic field adjacent its sputtering face to increase the density of the plasma and thereby increase the sputtering rate. The magnetron 110, which is relatively small, is rotated about the central axis of the chamber to provide more uniform target erosion and wafer coating. For a high target power and a small strong magnetron, a substantial number of the sputtered atoms are ionized. An RF power source 116 electrically biases the pedestal electrode 94 through a capacitive coupling circuit 118 to create a negative DC self-bias on the wafer 96 to accelerate argon and target ions towards the wafer 96.

A sputter coating of titanium nitride is achieved by a nitrogen gas source 120 supplying nitrogen gas into the vacuum chamber 92 through another mass flow controller 122. In a process referred to as reactive sputtering, the nitrogen reacts with the sputtered titanium atoms to form a layer of titanium nitride on the surface of the wafer 96.

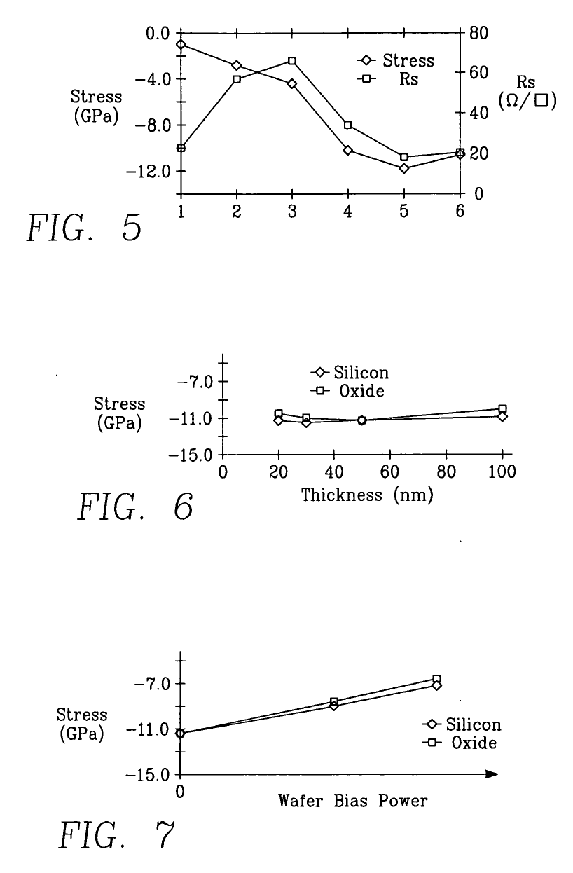

Using a sputter chamber like that of FIG. 4, a series of TiN films were grown under six differing sets of sputtering conditions. The films were then measured for their stress and for their sheet resistance R_{S}. The results plotted in FIG. 5 demonstrate that the stress produced in the TiN film can be modulated between about −1 GPa and −12 GPa by proper control of the sputtering conditions. As a result, stress and strain of magnitude of 4 GPa and greater and even 7 Pa and greater are readily and controllable achievable in contrast the general limit of 3 GPa. The resistance of the TiN nitride film is preferably as large as possible. However, the experiments demonstrated that with one major exception, the sheet resistance varies inversely with the compressive stress between values of about 18 and 75 ohms per square.

More systematic experiments were performed by growing high-strain TiN film on either a bare silicon wafer or on 300 nm of silicon oxide thermally oxidized on silicon wafers. As illustrated in the graph of FIG. 6, between thicknesses of 20 and 100 nm, there is a small but measurable variation of compressive stress with thickness and comparable stresses on both compositions of substrate. The thinner films are especially advantageous for the tight geometries anticipated in future IC generations. Films were also grown on the two substrates with differing values of RF bias power applied to the pedestal electrode. As illustrated in the graph of FIG. 7, the maximum compressive stress occurs with no wafer biasing and the compressive stress decreases with increasing bias power. The difference between substrate materials is observed to be very small.

The titanium nitride of the invention need not be a pure stoichiometric compound of TiN but may have varying amounts of the titanium and the nitrogen as long as the resulting material is electrically conductive and considered a metal. The titanium nitride may contain lesser amounts of other elements as long as the titanium and nitrogen constitute the two largest atomic fractions. In particular, there may be some oxygen substitution for the nitrogen. Further, the invention is not limited to titanium nitride. Other stress-inducing metal-containing layers may be used, for example, a metal nitride such as tantalum nitride or tungsten nitride. Other examples of the metals include other refractory metals such as Sr, Hf, V, Nb, Ta, Cr, and Mo. For purposes of the invention, silicon is not considered a metal component in a strain-inducing layer since neither SiN nor SiO₂ is conductive.

Although the strain-inducing metal layer is advantageously applied to a MOS transistor to increase the mobility within its channel, it may be applied to other semiconducting silicon devices benefitting from strain. It is understood that the silicon may be doped or alloyed, for example, with germanium, as long as the resulting material exhibits the band structure and general mobility characteristics of pure silicon.

The strain layer of the invention may be deposited in other sputtering chamber, such as one including an RF coil for the plasma source region. It is also possible that CVD-grown films provide the desired strain under the proper growth conditions.

The invention thus enables large and controllable amounts of strain into silicon using a well known material and which can be deposited from an economical source.

1. A stained MOS transistor, comprising:
a substrate including a channel region of semiconducting silicon; and
a strain-inducing layer of a metal compound formed over the substrate in an area of the channel region to have strain and inducing strain in the channel region.

2. The transistor of claim 1, wherein the metal compound is a nitride.

3. The transistor of claim 2, wherein the metal compound comprises titanium nitride.

4. The transistor of claim 3, wherein the substrate further includes p-type source and drain regions on either side of the channel region, wherein the strain-inducing layer is formed to sides of the channel region.

5. The transistor of claim 3, wherein the substrate further includes n-type source and drain regions on either side of the channel region and wherein the strain-inducing layer is formed directly over a center of the channel region.

6. The transistor of claim 3, wherein the strain is compressive strain having a magnitude of at least 4 gigapascal.

7. The transistor of claim 6, wherein the compressive strain has a magnitude of at least 7 gigapascal.

8. The transistor of claim 1, wherein the substrate further includes p-type drain regions on either side of the channel region, wherein the strain-inducing layer is formed to sides of the channel region but not directly over a center of the channel region.

9. The transistor of claim 1, wherein the substrate further includes n-type source and drain regions on either side of the channel region, wherein the strain is compressive strain, and wherein the strain-inducing layer is formed directly over a center of the channel region.

10. A strained MOS transistor, comprising:
a substrate including a channel region of semiconducting silicon; and
a strain-inducing layer of a titanium nitride formed over the substrate in an area of the channel region and inducing strain in the channel region.

11. The transistor of claim 10, further comprising p-type source and drain regions formed on either side of the channel region and wherein the strain-inducing layer is formed to sides of the channel region and not directly over a center thereof

12. The transistor of claim 10, further comprising n-type source and drain regions formed on either side of the channel region and wherein the strain-inducing layer is formed directly over a center of the channel region.

13. A method of inducing strain in silicon comprising sputter depositing a strain-inducing layer comprising a metal compound over a silicon substrate to form a region adjacent a channel region of a MOS transistor formed in the silicon substrate and inducing strain therein.

14. The method of claim 13, wherein the metal compound comprises a metal nitride.

15. The method of claim 14, wherein the metal nitride comprises titanium nitride.

16. The method of claim 13, wherein the metal compound is deposited in a plasma sputter chamber having a pedestal electrode supporting the silicon substrate in opposition to a target comprising a metal of the metal compound.

17. The method of claim 16, wherein the target comprises a titanium sputtering surface and additionally comprising admitting nitrogen into the sputter chamber.

18. The method of claim 16, wherein a bias power applied to the pedestal electrode substrate is selected to achieve a predetermined level of strain in the metal compound.

19. The method of claim 13, wherein the strain is compressive strain.

20. The method of claim 18, wherein the metal compound comprises titanium nitride and the predetermined level of strain has a magnitude of at least 4 gigapascal.

21. The method of claim 20, wherein the MOS transistor is a PMOS transistor and the strain-inducing layer is deposited to sides of the channel region but not directly thereover.

22. The method of claim 20, wherein the MOS transistor is an NMOS transistor and the strain-inducing layer is deposited directly over the channel region.
